(19) United States
(12) Patent Application Publication
(10) Pub. No.: US 2026/0198335 A1
(43) Pub. Date: Jul. 9, 2026

(54) DOUBLE-SIDED BOTTOM-UP PLATING OF THROUGH GLASS VIAS USING A PEELABLE CORE

(71) Applicant: Intel Corporation, Santa Clara, CA (US)

(72) Inventors: Whitney Bryks, Tempe, AZ (US); Houssam Jomaa, San Diego, CA (US); Jieying Kong, Chandler, AZ (US); Hiroki Tanaka, Gilbert, AZ (US); Wendy Lin, Chandler, AZ (US)

(73) Assignee: Intel Corporation, Santa Clara, CA (US)

(21) Appl. No.: 19/011,324

(22) Filed: Jan. 6, 2025

(51) Int. Cl. H01L 23/538; H01L 21/48; H01L 23/15; H01L 23/498

(52) U.S. Cl. CPC H10W 70/611; H10W 70/095; H10W 70/635; H10W 70/69; H10W 70/692

(57) ABSTRACT

Double-sided bottom-up plating of through glass vias, and related packages, apparatuses, and systems are discussed. Glass substrates for use in an integrated circuit package each have a first surface, an opposing second surface, and an opening extending between the first and second surfaces. A polymeric material is formed over the first surface and covering the opening, and the polymeric material is then collapsed to expose the opening while providing an adhesive material over the first surface. Two glass substrates are attached to a metal cladding of a peelable core using the adhesive material, and the openings are filled with metal using simultaneous bottom-up plating from the metal cladding. A peelable layer of the peelable core is then exposed and the glass substrates are removed from the peelable core and deployed in the package.

### BACKGROUND

Higher performance, lower cost, increased miniaturization, greater packaging density, and increased product flexibility of integrated circuit (IC) devices are ongoing goals of the electronics industry. IC packaging is a stage of semiconductor or IC device fabrication in which an IC that has been monolithically fabricated on a chip (or die) is assembled into a package that protects the IC chip from physical damage and communicatively connects the IC to other packaged IC chips and/or a scaled host component, such as a package substrate, or a printed circuit board. Multiple chips can be co-assembled, for example, into a multi-die package. Some package architectures include an IC die attached to a glass substrate and coupled to electrically conductive through-glass vias (TGVs) extending through the glass substrate.

Glass substrates have advantages such as low dielectric loss, high thermal stability, and improved surface planarity and surface quality. However, glass core failures such as cracks are observed due to high stress in the TGV from copper seed/glass interface during thermal processing. For example, TGVs generate stress due to the coefficient of thermal expansion (CTE) mismatch between glass and plated copper TGVs. This is accentuated by high-temperature processing (e.g. >250 C) since the heated copper expands, which stresses the glass, and upon cooling the copper shrinks more than the glass and leaves residual tensile stress in the glass, which, in turn, compromises its strength under bending modes.

Current solutions for these problems include using higher CTE glass, using via-in-vias where an opening is plugged with a dielectric material and the metal via is formed within the dielectric material, and using conformal plating and backfill with dielectric. However, these solutions have drawbacks including higher CTE glass having higher dopant concentrations and lower quality, loss of metal via size and density, and sacrifice of metal via volume, respectively. It is with respect to these and other considerations that the present improvements have been needed. Such improvements may become critical as the desire to deploy high-performance IC packages in various devices and systems becomes more widespread.

### BRIEF DESCRIPTION OF THE DRAWINGS

The material described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Further, where considered appropriate, reference labels have been repeated among the figures to indicate corresponding or analogous elements. In the figures:

FIG. 1 is a flow diagram illustrating example methods for fabricating and assembling glass substrate structures having bottom-up plated through glass vias;

FIGS. 2, 3, 4, 5, 6, 7, 8, 9, 10, 11, 12, 13, 14, 15, and 16 are illustrations of cross-sectional side views of glass substrate structures as the methods of FIG. 1 are practiced to form bottom-up plated through glass vias;

FIGS. 17, 18, and 19 are illustrations of cross-sectional side views of package structures as the methods of FIG. 1 are practiced to assemble a package assembly having a glass substrate with bottom-up plated through glass vias;

FIG. 20 illustrates exemplary systems employing an IC assembly including a glass core substrate with bottom-up plated through glass vias; and

FIG. 21 is a block diagram of a computing device, all arranged in accordance with at least some implementations of the present disclosure.

### DETAILED DESCRIPTION

One or more embodiments or implementations are now described with reference to the enclosed figures. While specific configurations and arrangements are discussed, it should be understood that this is done for illustrative purposes only. Persons skilled in the relevant art will recognize that other configurations and arrangements may be employed without departing from the spirit and scope of the description. It will be apparent to those skilled in the relevant art that techniques and/or arrangements described herein may also be employed in a variety of other systems and applications other than what is described herein.

Reference is made in the following detailed description to the accompanying drawings, which form a part hereof, wherein like numerals may designate like parts throughout to indicate corresponding or analogous elements. It will be appreciated that for simplicity and/or clarity of illustration, elements illustrated in the figures have not necessarily been drawn to scale. For example, the dimensions of some of the elements may be exaggerated relative to other elements for clarity. Further, it is to be understood that other embodiments may be utilized, and structural and/or logical changes may be made without departing from the scope of claimed subject matter. It should also be noted that directions and references, for example, up, down, top, bottom, over, under, and so on, may be used to facilitate the discussion of the drawings and embodiments and are not intended to restrict the application of claimed subject matter. Therefore, the following detailed description is not to be taken in a limiting sense and the scope of claimed subject matter defined by the appended claims and their equivalents.

In the following description, numerous details are set forth. However, it will be apparent to one skilled in the art, that the present invention may be practiced without these specific details. In some instances, well-known methods and devices are shown in block diagram form, rather than in detail, to avoid obscuring the present invention. Reference throughout this specification to “an embodiment” or “one embodiment” means that a particular feature, structure, function, or characteristic described in connection with the embodiment is included in at least one embodiment of the invention. Thus, the appearances of the phrase “in an embodiment” or “in one embodiment” in various places throughout this specification are not necessarily referring to the same embodiment of the invention. Furthermore, the particular features, structures, functions, or characteristics may be combined in any suitable manner in one or more embodiments. For example, a first embodiment may be combined with a second embodiment anywhere the particular features, structures, functions, or characteristics associated with the two embodiments are not mutually exclusive.

As used in the description of the invention and the appended claims, the singular forms “a”, “an” and “the” are intended to include the plural forms as well, unless the context clearly indicates otherwise. It will also be understood that the term “and/or” as used herein refers to and encompasses any and all possible combinations of one or more of the associated listed items. Herein, the term “predominantly” indicates not less than 50% of a particular material or component while the term “substantially pure” indicates not less than 99% of the particular material or component and the term “pure” indicates not less than 99.9% of the particular material or component. Unless otherwise indicated, such material percentages are based on atomic percentage. Herein the term concentration is used interchangeably with material percentage and also indicates atomic percentage unless otherwise indicated.

The terms “coupled” and “connected,” along with their derivatives, may be used herein to describe structural relationships between components. It should be understood that these terms are not intended as synonyms for each other. Rather, in particular embodiments, “connected” may be used to indicate that two or more elements are in direct physical or electrical contact with each other. “Coupled” may be used to indicated that two or more elements are in either direct or indirect (with other intervening elements between them) physical or electrical contact with each other, and/or that the two or more elements co-operate or interact with each other (e.g., as in a cause an effect relationship).

The terms “over,” “under,” “between,” “on”, and/or the like, as used herein refer to a relative position of one material layer or component with respect to other layers or components. For example, one layer disposed over or under another layer may be directly in contact with the other layer or may have one or more intervening layers. Moreover, one layer disposed between two layers may be directly in contact with the two layers or may have one or more intervening layers. In contrast, a first layer “on” a second layer is in direct contact with that second layer. Similarly, unless explicitly stated otherwise, one feature disposed between two features may be in direct contact with the adjacent features or may have one or more intervening features. The term immediately adjacent indicates such features are in direction contact. Furthermore, the terms “substantially,” “close,” “approximately,” “near,” and “about,” generally refer to being within +/−10% of a target value. The term layer as used herein may include a single material or multiple materials. As used in throughout this description, and in the claims, a list of items joined by the term “at least one of” or “one or more of” can mean any combination of the listed terms. For example, the phrase “at least one of A, B or C” can mean A; B; C; A and B; A and C; B and C; or A, B and C.

Apparatuses, systems, and methods are described herein related to double-sided bottom-up plating of through glass vias within openings of two glass core substrates that are attached to a core having an electrically conductive foil used as a seed for the plating. After plating, a peelable layer under the foil is accessed by cutting through the foil, and the glass core substrates are released using the peelable layer.

As described above, current package architectures may include one or more IC dies attached to a glass substrate and coupled to electrically conductive through-glass vias (TGVs) extending through the glass substrate. However, current fabrication techniques have difficulties including glass core failures due to high mechanical stresses at the copper seed/glass interface during thermal processing. In particular, the high coefficient of thermal expansion (CTE) mismatch between the via metallization and the glass core cause difficulties when typical copper seed and plating techniques are used. Embodiments discussed herein enable the use of double-sided bottom-up plating such as copper plating from a foil at one side of an opening through the glass substrate to at least partially decouple the TGV from the sidewall of the glass substrate by not having a seed layer directly deposited on the sidewall. Thereby, the CTE mismatch between the via metallization and the glass is mitigated and the stress therebetween is reduced. This, in turn, reduces failures such as glass core substrate cracks. Furthermore, the discussed techniques enable two substrates to be plated simultaneously for improved throughput. Notably, plating is a relatively slow process and can be a bottleneck in a package process flow.

As discussed, the via metallization within the openings of the glass core is absent a seed layer, which can be a different material than the bulk (e.g., a titanium-copper seed layer for a bulk copper) or a different microstructure (e.g., a seed layer having a different grain size than the bulk metal). In some embodiments, an entirety of the via metallization disclosed herein is a substantially pure (99%+) or pure (99.9%+) metal such as substantially pure or pure copper having a constant microstructure throughout. As used herein, the term microstructure indicates the microscopic structure of the material and refers to the arrangement of the materials constituents such as grains, defects, grain boundaries, etc. The term constant throughout is used to indicate each portion of the material has the same or similar microstructure in each of the regions. In some embodiments, the via metallization is physically decoupled at least partially (e.g., at some positions) from the sidewall of the opening within the glass such that an air gap is evident between the via metallization and the sidewall. The term air gap indicates a gap that is filled with any pertinent ambient gas. The ambient gas may be present during the formation of the gap (i.e., if the air gap is pinched off) or the ambient gas may be provided at any subsequent time. Notably, the term air gap does not necessarily indicate a gap filled with atmospheric air but instead indicates a gap filled with ambient gas, in accordance with its use in the art.

In some embodiments, a polymeric material such as a dielectric is applied to one surface of a glass substrate having openings therein (e.g., a panel having TGV openings) while leaving the openings at least partially exposed. This coating material is used as a bonding adhesive to bond two such prepared glass substrates, one on each side, to a core having a peelable layer and a metal seed layer over the peelable layer (e.g., a peelable core). This allows for simultaneous bottom-up plating of two TGV substrates followed by mechanical peeling after access of the peelable layer (i.e., by cutting through the meatal seed layer). Such techniques effectively double electroplating throughput and offer the advantage of lower glass substrate stress, as discussed.

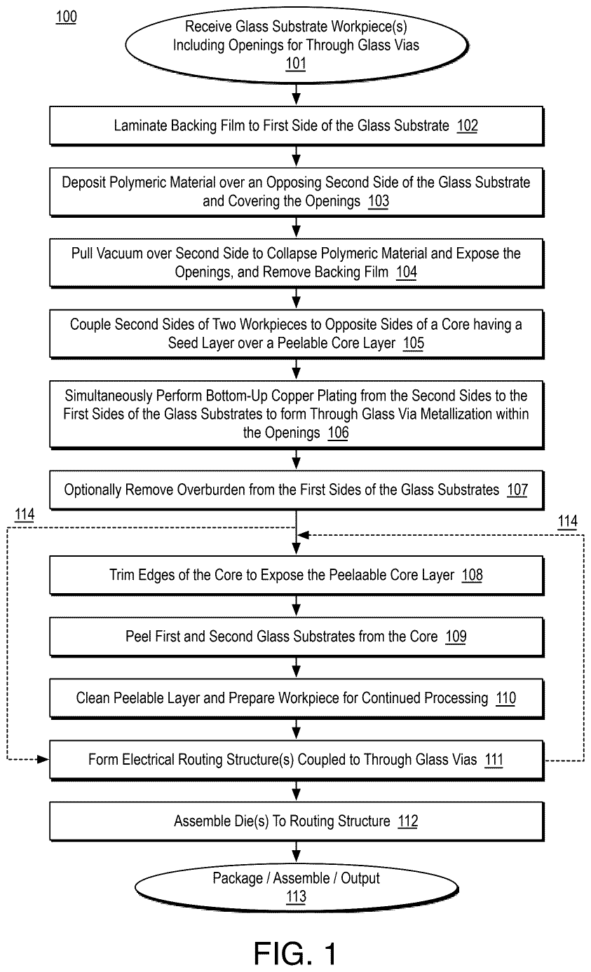

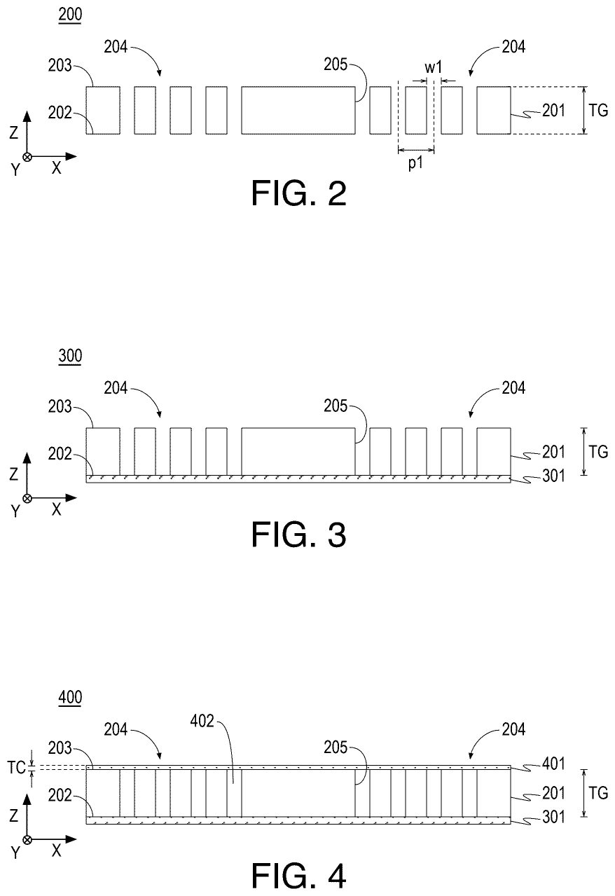

FIG. 1 is a flow diagram illustrating example methods 100 for fabricating and assembling glass substrate structures having bottom-up plated through glass vias, arranged in accordance with at least some implementations of the present disclosure. For example, methods 100 may be implemented to fabricate any glass substrates structures, package structures, or assemblies discussed herein. In the illustrated embodiment, methods 100 include one or more operations as illustrated by operations 101-113. However, embodiments herein may include additional operations, certain operations being omitted, or operations being performed out of the order provided. FIGS. 2-19 illustrate structures and components as methods 100 are practiced.

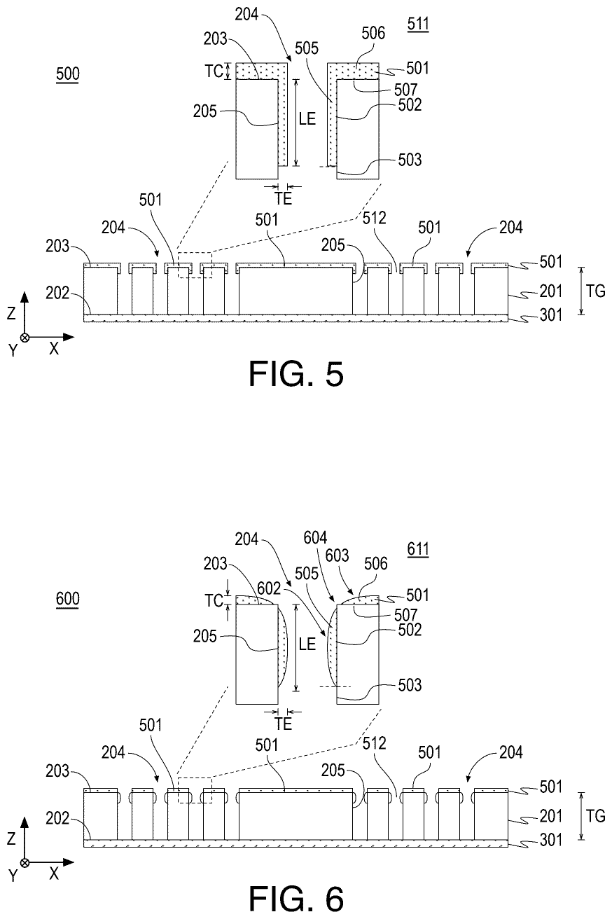

FIGS. 2, 3, 4, 5, 6, 7, 8, 9, 10, 11, 12, 13, 14, 15, and 16 are illustrations of cross-sectional side views of glass substrate structures as methods 100 are practiced to form bottom-up plated through glass vias, arranged in accordance with at least some implementations of the present disclosure. FIGS. 5, 6, 7, 8, 9, and 16 further include close-up views and/or top-down views of features of bottom-up plated through glass vias, arranged in accordance with at least some implementations of the present disclosure. FIGS. 17, 18, and 19 are illustrations of cross-sectional side views of package structures as methods 100 are practiced to assemble a package assembly having a glass substrate with bottom-up plated through glass vias, arranged in accordance with at least some implementations of the present disclosure. Methods 100 provide a process flow for bottom-up plating of TGVs by coating a liquid adhesive on a glass substrate such that openings within the glass substrate are left open to bottom-up plating from a metal foil attached to the adhesive.

Methods 100 begins at operation 101, where any number of workpieces such as glass substrates each including a thickness of glass and any number of holes or openings extending through the thickness of the glass are received. The workpieces may be prepared upstream of methods 100 and may be in a large panel format, a wafer format, or the like. In addition to the thickness of glass, the workpiece received at operation 101 may include one or more materials upon which electrical routing structures may be formed.

FIG. 2 is an illustration of a cross-sectional side view of a glass substrate structure 200 including materials received for processing such as a glass substrate 201 having a first surface 202, an opposing second surface 203, and a thickness TG extending between first surface 202 and second surface 203, and orthogonal to both. Notably, at least two glass substrates 201 are prepared according to the discussed techniques prior to attachment to a peelable core for plating as discussed herein below. Each of the glass substrates 201 may be prepared in the same manner, or differently prior to double-sided bottom-up plating. As discussed below, IC device package structures may be advantageously fabricated upon glass substrate 201 as flatness and/or thickness control for a preform of glass is superior to that of starting substrates based on organic materials (e.g., epoxy), and costs can be significantly lower than for monocrystalline materials (e.g., silicon).

Glass substrate 201 is a solid bulk material layer that may have been previously formed into any shape in plan view (e.g., x-y plane) suitable for a packaging workpiece, such as a rectangular shape. Glass substrate 201 has a thickness TG that may vary with implementation, for example, to limit warpage while remaining thin enough to permit the formation of through glass vias. In some embodiments, thickness TG is not less than 200 μm and not more than 2000 μm. In some embodiments, thickness TG is advantageously not less than 350 μm and not more than 1000 μm such as a thickness of 400 μm.

In some embodiments, glass substrate 201 is predominantly silicon and oxygen. In some embodiments, glass substrate 201 includes at least 23 percent silicon and at least 26 percent oxygen, by weight (i.e., wt. %). Glass substrate 201 may further include one or more additives, such as, aluminum, boron, magnesium, calcium, barium, tin, sodium, potassium, strontium, phosphorus, zirconium, lithium, titanium, or zinc. In embodiments where glass substrate 201 includes at least 23 wt. % Si and at least 26 wt. % O, glass substrate 201 may further include at least 5 wt. % Al. Additives within glass substrate 201 may form suboxides (A₂O) monoxides (AO), binary oxides (AO₂), ternary oxides (ABO₃), and mixtures thereof. For example, glass substrate 201 may include AlOₓ (e.g., Al₂O₃), BOₓ (e.g., B₂O₃), MgOₓ (e.g., MgO), CaOₓ (e.g., CaO), SrOₓ (e.g., SrO), BaOₓ (e.g., BaO), SnOₓ (e.g., SnO₂), NaOₓ (e.g., Na₂O), KOₓ (e.g., K₂O), POₓ(e.g., P₂O₃), ZrOₓ (e.g., ZrO₂), LiOₓ (e.g., Li₂O), TiOₓ (e.g., TiO₂), or ZnOₓ (e.g., ZnO₂). In some embodiments, glass substrate is a BF33 glass. Depending on chemical composition, glass substrate 201 may therefore be referred to as silica, fused silica, aluminosilicate, borosilicate, or alumino-borosilicate, for example.

In some embodiments, glass substrate 201 is advantageously a bulk material of substantially homogeneous composition in contrast to a composite material that may merely include glass fillers and/or fibers. Although glass substrate 201 is substantially amorphous in some embodiments, glass substrate 201 may also have other morphology or microstructure, such as polycrystalline (e.g., nanocrystalline). In some embodiments, glass substrate 201 is rectangular in shape in plan view. However, other shapes may be used. In some embodiments, glass substrate 201 is a layer of glass having a thickness of not less than 50 μm, a first length of not less than 10 mm and a second length orthogonal to the first length of not less than 10 mm. In some embodiments, glass substrate 201 is absent any organic adhesive or other organic material. Although not depicted, one or more material layers may clad either or both of first surface 202 and second surface 203 of glass substrate 201 so that glass substrate 201 is a bulk or core layer of a multi-layered substrate. Exemplary cladding materials include inorganic materials such as silicon nitride (SiNₓ) or silicon oxynitride (SiOₓN_{y}). In other embodiments, a silicon layer (polycrystalline or monocrystalline) may clad one or both sides of glass substrate 201. Organic material layers, such as polymer dielectric materials, may also clad one or more sides of glass substrate 201. Hence, while glass substrate 201 is advantageously substantially free of organic materials (e.g., no adhesives, etc.), a workpiece may include organic within a substrate stack that includes glass substrate 201. Such claddings or build-up layers may be fabricated on glass substrate 201 as discussed herein below.

As shown, holes, through holes, or openings 204 in glass substrate 201 extend from first surface 202 to second surface 203 and through thickness TG of glass substrate 201. Furthermore, openings 204 define sidewalls 205 of glass substrate 201 that also extend from first surface 202 to second surface 203. Openings 204 may be formed using any suitable technique or techniques such as laser assisted etch techniques with a dual side etch or single side etches. Although illustrated with openings 204 having a constant width or diameter throughout thickness TG, in some embodiments, openings 204 may have a dual taper profile or a single tape profile as is known in the art.

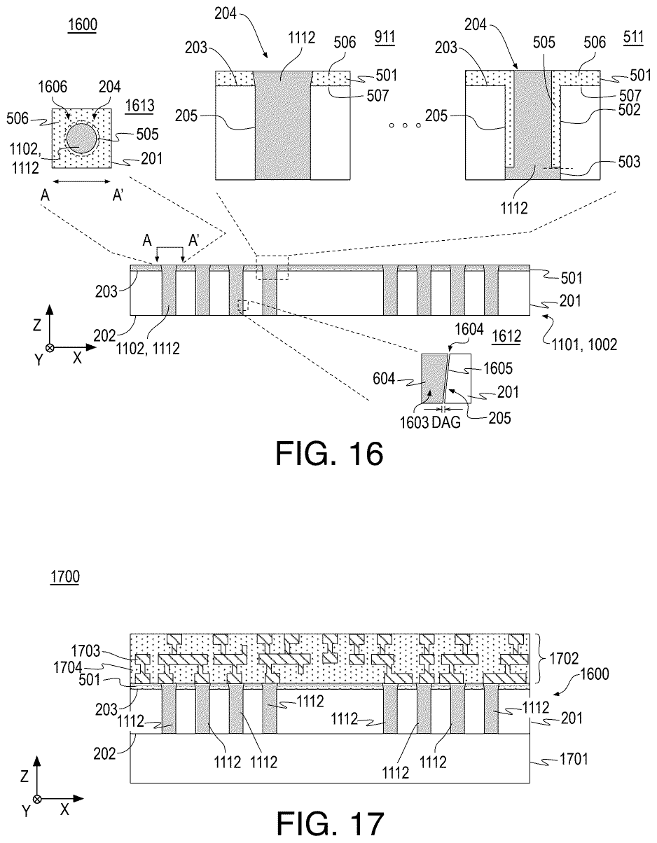

Openings 204 may have any suitable lateral cross-sectional shape in the x-y plane such as circular or oval (see FIG. 16). Openings 204 have a diameter or cross-sectional width w1 (a longest distance across opening 204 in the x-y plane) and may have an optional taper defining a taper width and a corresponding taper angle. Openings 204 may have any suitable cross-sectional width w1 such as a width w1 in the range of about 15 to 80 μm. Furthermore, the thickness TG of glass substrate 201 over the width w1 of openings 204 defines an aspect ratio of openings 204. Notably, the techniques discussed herein enable the fill of higher aspect ratio openings 204. In some embodiments, the aspect ratio (AR=TG/w1) of openings 204 is not less than 5 (i.e., for a 400 μm thickness TG, opening widths w1 of not more than 80 μm). In some embodiments, the aspect ratio of openings 204 is not less than 10 (i.e., for a 400 μm thickness TG, opening widths w1 of not more than 40 μm). In some embodiments, the aspect ratio of openings 204 is not less than 20 (i.e., for a 400 μm thickness TG, opening widths w1 of not more than 20 μm). Other aspect ratio via metallizations may be used. It is noted that the discussed dimensions of openings 204 carry over to the resultant via metallizations formed within openings 204 and the via metallizations discussed herein below may have of the same dimensions, shapes, and characteristics.

Returning to FIG. 1, methods 100 continue at operation 102, where a backing film is optionally laminated or otherwise attached to a first side of the glass substrate. The backing film may have any suitable composition and may be of any suitable thickness and rigidity such that the backing film seals a first side of the discussed openings of the glass substrate. Furthermore, the backing film may be attached to the glass substrate using any suitable technique or techniques such as a removable adhesive, a releasable tape, or the like.

FIG. 3 is an illustration of a cross-sectional side view of a glass substrate structure 300 similar to glass substrate structure 200 after attaching a backing film or material layer 301 that substantially covers first surface 202 and seals one side of each of openings 204 at first surface 202. Material layer 301 may be any material that provides a seal for openings 204 and is mechanically strong enough to withstand subsequent processing discussed herein below. In some embodiments, material layer 301 is a polymer material such as polyethylene terephthalate (PET). As discussed, material layer 301 may be attached to first surface 202 using any suitable technique or techniques such as lamination techniques. In some embodiments, material layer 301 is releasable using, for example, a UV releasable film. In some embodiments, material layer 301 is a tape as commonly used in back-end processes, for example, a dicing tape.

Returning to FIG. 1, methods 100 continue at operation 103, where a polymeric material such as an adhesive material is coated on the second surface of the glass substrate, opposite the backing film or material layer attached to the first surface at operation 102. Notably, the polymeric material is a material selected, and deposited at a particular thickness, such that it substantially coats the second surface and bridges over the openings for subsequently formed via metallizations. The bridging of the openings traps air within the openings for subsequent collapse of the polymeric material. Such a state with a thin polymer film suspended over trapped air can be characterized as tented. Therefore, the polymeric material and its thickness are selected such that subsequent processing can collapse the portions of the material that bridge over the openings to re-expose the openings for via metallization. Such techniques may be characterized as tent-collapse techniques, for example.

FIG. 4 is an illustration of a cross-sectional side view of a glass substrate structure 400 similar to glass substrate structure 300 after deposition of an adhesive or polymeric material 401 on second surface 203 of glass substrate 201 such that polymeric material 401 covers second surface 203 inclusive of bridging or spanning openings 204 to provide trapped air 402 within openings 204. Polymeric material 401 may be deposited using any suitable technique or techniques. In some embodiments, polymeric material 401 is deposited by a slit coating process. However other techniques such as a spin coating process or a spray coating process may be used.

Polymeric material 401 may be any suitable material that coats second surface 203 and spans openings 204 but is susceptible to collapse processing, as discussed below. In some embodiments, polymeric material 401 is one of an epoxy material, a polyimide material, a benzocyclobutene based material, a polyethylene terephthalate based material, a high-density polyethylene material or a polyethylene based material. In some embodiments, polymeric material is a build-up film such as Ajinomoto build-up film (ABF). Polymeric material 401 or portions thereof may remain in the resultant package formed using glass substrate 201 to provide additional adhesion properties for the resultant via metallization or other components and/or improved insulation.

Polymeric material 401 may be applied to any suitable thickness TC (coating thickness). The thickness TC is orthogonal to second surface 203 (i.e., thickness TC is in the z-dimension) and may be any suitable value. In some embodiments, thickness TC is not less than 2 μm and not more than 20 μm. In some embodiments, thickness TC is not less than 5 μm and not more than 10 μm. In some embodiments, thickness TC is not less than 4 μm and not more than 8 μm. In some embodiments, thickness TC is not more than 8 μm. In some embodiments, thickness TC is about 8 μm.

Trapped air 402 is thereby trapped within openings 204. The term trapped air indicates an opening is filled with any pertinent ambient gas. The ambient gas may be present during the formation of polymeric material 401 to seal openings 204. Notably, the air in this context does not necessarily indicate a fill of atmospheric air but instead indicates a fill with the ambient gas during its formation, in accordance with the use of the term in the art.

Returning to FIG. 1, methods 100 continue at operation 104, where the polymeric material deposited at operation 103 is collapsed using any suitable technique or techniques such as pulling a vacuum over the second side of the glass substrate to collapse (e.g., tent-collapse) the material bridging the openings to re-expose the openings for eventual via metallization. The discussed techniques open (or re-open) the openings and provide an uncured polymeric or adhesive layer (e.g., ABF) on the surface for use as an adhesive to a metal seed layer built up over a peelable core, as discussed below. While not being bound by theory, pulling vacuum over the polymeric material may pull the air trapped in the opening through the polymeric material (e.g., by diffusion through the polymeric material), and release of the vacuum (i.e., re-pressurization) may cause the polymeric material to collapse and at least partially tear to expose the openings of the glass substrate. Alternatively, the polymeric material may break under the vacuum and collapse toward and/or into the opening upon re-pressurization. In other embodiments, the collapse mechanism can be facilitated by an increase in atmospheric pressure rather than a decrease, such as by a high-pressure oven or similar process.

In some embodiments, the discussed coating and vacuum collapse procedure may be performed a single time, which may be followed by a soft bake prior to adhering the resultant polymeric material to a metal seed layer for bottom-up plating. In other embodiments, the coating, vacuum, and soft bake process may be repeated any number of times using the same or different materials. In some embodiments, the coating, vacuum, and soft bake process is repeated twice, three times, four times, or more. The material used in the coating process may be the same or they may be different. Alternatively, a multi-material layer may be coated prior to vacuum collapse. Such embodiments are discussed further herein below.

FIG. 5 is an illustration of a cross-sectional side view of a glass substrate structure 500 similar to glass substrate structure 400 after tent-collapse of polymeric material 401 to form adhesive or polymeric coating structure 501 on second surface 203 of glass substrate 201 such that polymeric coating structure 501 covers second surface 203 but leaves at least portions 512 of openings 204 exposed. Polymeric coating structure 501 or components or portions thereof may be characterized as a polymeric material structure, a material structure, a polymeric material, or the like. Furthermore, in some embodiments, a portion of polymeric coating structure 501 extends into openings 204 such that a portion of polymeric coating structure 501 is on a region or portion of sidewall 205 while another region or portion of sidewall 205 is exposed.

As shown, polymeric coating structure 501 is deposited and collapsed such that glass substrate 201 includes openings 204 extending from first surface 202 to opposing second surface 203 with polymeric coating structure 501 leaving at least portions 512 of each of openings 204 exposed. Polymeric coating structure 501 may be formed using slit coating followed by vacuum induced collapse, as discussed. The material of polymeric coating structure 501 may be any suitable material that coats second surface 203, leaves portions 512 of each of openings 204 exposed, and provides sufficient adhesion to a subsequent metal foil. In some embodiments, polymeric coating structure 501 is one of an epoxy material, a polyimide material, a benzocyclobutene based material, a polyethylene terephthalate based material, a high-density polyethylene material or a polyethylene based material. Although discussed with respect to polymeric materials, other suitable material systems may be used.

As shown in enlarged view 511, a top surface portion 506 of polymeric coating structure 501 is on a portion 507 of second surface 203 at any suitable thickness TC discussed above. Polymeric coating structure 501 further has an extension 505 that extends a particular length LE (extension length) into openings 204 along sidewall 205. Within openings 204, extension 505 of polymeric coating structure 501 may have the same thickness TC as top surface portion 506 of polymeric coating structure 501 or extension 505 of polymeric coating structure 501 may have lesser thickness TE (extension thickness). Extension 505 is on a region or portion 502 of sidewall 205 while region or portion 503 of sidewall 205 is exposed. Notably, extension 505 and portion 506 of polymeric coating structure 501 have the same composition.

The thickness TE of extension 505 is orthogonal to sidewall 205 and may be any suitable thickness. In some embodiments, thickness TE is not less than 1 μm and not more than 10 μm. In some embodiments, thickness TE is not less than 1 μm and not more than 4 μm. In some embodiments, thickness TE is not less than 0.5 μm and not more than 3 μm. In some embodiments, thickness TE is not more than 4 μm. In some embodiments, thickness TE is about 3 μm. In some embodiments, a ratio of thickness TE to thickness TC (TE/TC) is not more than 0.7. In some embodiments, a ratio of thickness TE to thickness TC (TE/TC) is not more than 0.6. In some embodiments, a ratio of thickness TE to thickness TC (TE/TC) is not more than 0.5. Other ratios may be used. The length LE of extension 505 is along sidewall 205 and may be of any suitable value. In some embodiments, length LE is not less than 20 μm and not more than 100 μm. In some embodiments, length LE is not less than 50 μm and not more than 70 μm. In some embodiments, length LE of extension 505 is not less than 60 μm and not more than 70 μm. In some embodiments, length LE of extension 505 is not less than 60 μm. Other thicknesses TC, TE and lengths LE may be used.

As discussed below, a via metallization is formed within opening 204 and on at least portions of polymeric coating structure 501. After plating, polymeric coating structure 501 may continue to have any characteristic discussed herein and the resultant via metallization may be contained within opening 204 and the pertinent components of polymeric coating structure 501. In some embodiments, the resultant via metallization is directly on extension 505 within opening 204 such that extension 505 is between the via metallization and portion 502 of sidewall 205, and the resultant via metallization is immediately adjacent portion 503 of sidewall 205.

Discussion now turns to alternative constructions of polymeric coating structure 501. The resultant via metallization may conform to any such constructions of polymeric coating structure 501.

FIG. 6 is an illustration of a cross-sectional side view of a glass substrate structure 600 similar to glass substrate structure 400 after tent-collapse to form polymeric coating structure 501 with extension 505 having a convex surface 602. As shown in enlarged view 611, in some embodiments, portion 506 of polymeric coating structure 501 also has a convex surface 603. While not bound by theory, convex surface 602 and convex surface 603 may be formed during collapse as the surface tension of the material collapse upon re-pressurization causes polymeric coating structure 501 to have convex surface 602 and convex surface 603.

As used herein, the term convex surface is used in its ordinary meaning to indicate a surface curved like the exterior of a circle or sphere. The convex shape of convex surface 602 may be curved along the z-dimension while the convex shape of convex surface 603 may be curved along any direction in the x-y plane. The convex shape of convex surface 602 and the convex shape of convex surface 603 may have a radius of curvature that is orders of magnitude greater than the thicknesses of extension 505 and portion 506. In some embodiments, the radius of curvature is not less than 10 times the thickness. In some embodiments, the radius of curvature is not less than 100 times the thickness. In some embodiments, the radius of curvature is not less than 200 times the thickness, or more.

As also shown in enlarged view 611, an edge 604 of opening 204 defined as an intersection of portion 507 of second surface 203 and portion 502 of sidewall 205 is absent polymeric coating structure 501. Again, while not bound by theory, edge 604 may be exposed during collapse as the surface tension of the material collapse upon re-pressurization causes polymeric coating structure 501 to recede to extension 505 and portion 506 having convex surface 602 and convex surface 603, respectively.

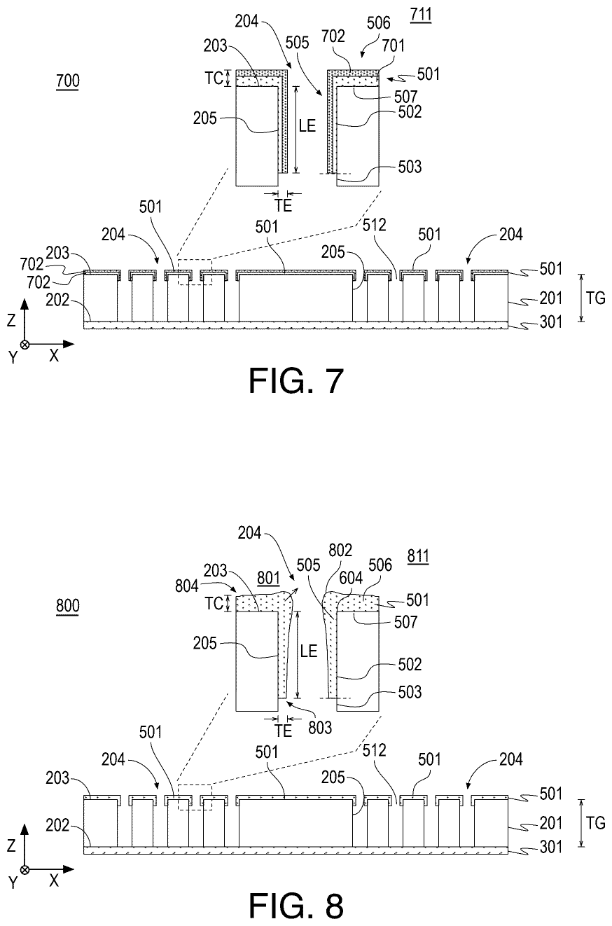

FIG. 7 is an illustration of a cross-sectional side view of a glass substrate structure 700 similar to glass substrate structure 400 after tent-collapse to form polymeric coating structure 501 having a multilayer stack including first polymeric material 701 directly on portions 502, 507 and second polymeric material 702 directly on first polymeric material 701 as shown in greater detail in enlarged view 711. Although illustrated with two polymeric materials 701, 702, polymeric coating structure 501 may include any number of polymeric material layers such as three, four, or more. In some embodiments, first polymeric material 701 is coated and collapsed as discussed with respect to operations 103, 104 followed by an optional soft bake, and then second polymeric material 702 is coated and collapsed again as discussed with respect to operations 103, 104 followed by an optional soft bake. However, in some embodiments, a multilayer polymeric stack is formed at operation 103 and the multilayer polymeric stack is collapsed as discussed with respect to operation 103, 104 to form polymeric coating structure 501 having a multilayer stack.

In some embodiments, polymeric materials 701, 702 are selected based on polymeric material 701 being directly on glass substrate 201 and polymeric material 702 being directly on a resultant via metallization. For example, polymeric material 701 may be selected for its adhesion to glass substrate 201 while polymeric material 702 is selected for its insulating properties, closer CTE match to the resultant via metallization, or adhesive properties with respect to the resultant via metallization. The materials of polymeric materials 701, 702 may be any of those discussed herein with respect to polymeric material 401. Furthermore, polymeric materials 701, 702 may together or each have any thicknesses TC, TE and lengths LE discussed herein above.

FIG. 8 is an illustration of a cross-sectional side view of a glass substrate structure 800 similar to glass substrate structure 400 after tent-collapse to form polymeric coating structure 501 having a protruding portion 802 at edge 604. In some embodiments, as shown in enlarged view 811, protruding portion 802 is formed by multiple layers of polymeric material coatings as illustrated by build-up direction 801. As discussed, in some embodiments, the coating, vacuum, and soft bake process may be repeated any number of times using the same or different materials. In some embodiments, the coating, vacuum, and soft bake process is repeated twice, three times, four times, or more. In some embodiments, repeating the coating, vacuum, and soft bake process causes protruding portion 802 at edge 604 as material gathers and forms build-up direction 801.

As shown, protruding portion 802 causes a taper 803 such that thickness TE of extension 505 decrease moving toward a center of opening 204 from edge 604. In some embodiments, the thickness at the bottom of extension 505 is not more than 75% of the thickness of extension 505 at edge 604. In some embodiments, the thickness at the bottom of extension 505 is not more than 50% of the thickness of extension 505 at edge 604. In some embodiments, the thickness at the bottom of extension 505 is not more than 40% of the thickness of extension 505 at edge 604. Other thickness ratios may be used. Similarly, portion 506 has a taper 804 such that thickness TC of portion decreases from edge 604 toward a position of second surface 203 away from opening 204. In some embodiments, the thickness at the position of portion 506 away from edge 604 is not more than 75% of the thickness of portion 506 at edge 604. In some embodiments, the thickness at the position of portion 506 away from edge 604 is not more than 50% of the thickness of portion 506 at edge 604. In some embodiments, the thickness at the position of portion 506 away from edge 604 is not more than 40% of the thickness of portion 506 at edge 604. Other thickness ratios may be used.

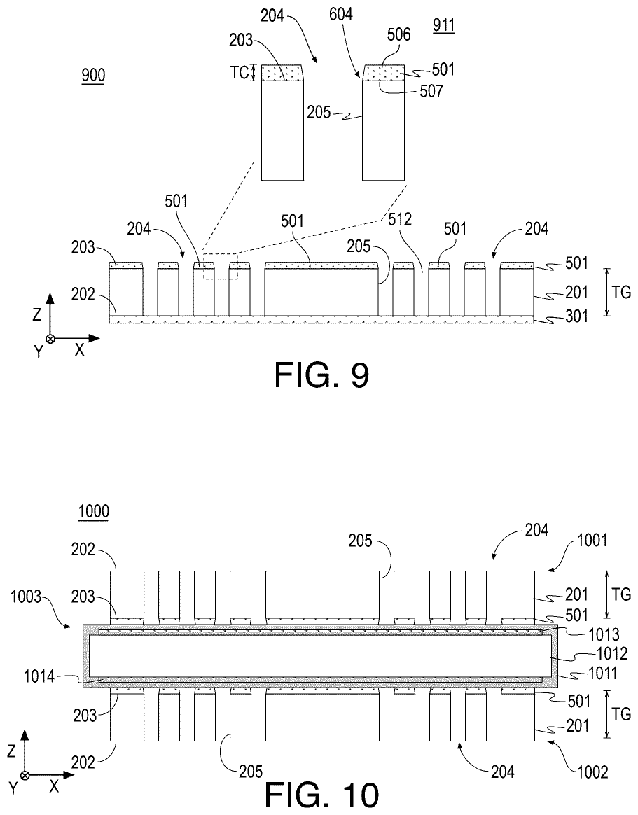

FIG. 9 is an illustration of a cross-sectional side view of a glass substrate structure 900 similar to glass substrate structure 400 after tent-collapse to form polymeric coating structure 501 absent polymeric material on sidewall 205 of opening 204. In some embodiments, as also shown in enlarged view 911, polymeric coating structure 501 is absent sidewall 205 and does not extend beyond edge 604 due to the discussed surface tension of the material collapse as well as edge effects caused by edge 604 which can cause contact angle effects in liquid or semi-liquid materials. In the following processing, where double-sided bottom-up plating is performed using a host substrate core, glass substrate structure 900 is used as an example. However, it is understood that any glass substrate structure having any characteristics discussed herein may be used.

Returning to FIG. 1, methods 100 continue at operation 105, where at least two prepared glass substrate structures having an adhesive or polymeric material on one side thereof and opening extending therethrough are attached, using the polymeric material, to a metal seed layer on opposing sides of a plating substrate. The plating substrate includes a core and a peelable layer on each side of the core. The plating substrate further includes a plating seed layer such as a metal foil that is on or over the peelable substrate. The prepared glass substrate structures are attached to the plating seed layer for simultaneous bottom-up plating of the exposed openings in the glass substrate structures. After plating, the peelable layer is exposed by, for example, cutting at least the metal foil, and the peelable layer is used to detach the glass substrate structures from the plating substrate. The glass substrate structures may then be further processed and assembled into a package, and the plating substrate may be discarded.

FIG. 10 is an illustration of a cross-sectional side view of a glass substrate structure 1000 similar to glass substrate structure 900 after removal of backing film or material layer 301 from two of glass substrate structures 900 and attachment of each to opposite sides of a peelable plating core 1003 as shown with respect to glass substrate structures 1001, 1002. Although illustrated with two of glass substrate structures 1001, 1002 having the same characteristics, any number of glass substrate structures 1001, 1002 may be used and they may be the same or they may be different. For example, any characteristics discussed herein may be deployed with respect to glass substrate structures 1001, 1002.

As shown, peelable plating core 1003 includes a substrate 1012, which may be any suitable material or structure such as a handle or a carrier. In some embodiments, substrate 1012 is a glass carrier; however, other materials may be used. Peelable plating core 1003 further includes release layers or peelable layers 1013, 1014 each on an opposing side of substrate 1012. Peelable layers 1013, 1014 may each be a removable adhesive, a releasable tape, or the like. Peelable layers 1013, 1014 may release after heat treatment, or peelable layers 1013, 1014 may release at room temperature. In some embodiments, one or more intervening layers such as adhesive layers or bonding layers are between peelable layers 1013, 1014 and each side of substrate 1012. Peelable plating core 1003 includes a metal seed layer 1011 on or over peelable layers 1013, 1014 and substrate 1012. Metal seed layer 1011 may be any suitable material or multi-layer material stack that provides for a seed for bottom-up via metallization plating. In some embodiments, metal seed layer 1011 is a metal foil such as a copper metal foil. In some embodiments, metal seed layer 1011 is a plated layer of copper or a multilayer stack having copper at outer surfaces of peelable plating core 1003. However, other material systems may be used. As shown, portions of metal seed layer 1011 are exposed within openings 204. It is also noted that sidewalls 205 of openings 204 are also exposed such that, advantageously, no seed material is tightly bound to sidewalls 205. Thereby, stress is reduced by the via metallizations formed herein below.

Returning to FIG. 1, methods 100 continue at operation 106, where a suitable metal is simultaneously plated in a bottom-up manner in openings in each of the glass substrates from the metal seed of the peelable plating core to fill the openings. In some embodiments, the plating is copper plating starting from a copper cladding of the peelable plating core. In some embodiments, the plating will plate through the opening in a bottom-up fashion until over plating is evident on the opposite side of the glass substrates. The resultant plated material has a consistent microstructure and morphology throughout. Notably, no seed material is evident at the sidewall of the plated opening (i.e., no other seed material nor different microstructure and morphology). Furthermore, one or more air gaps may exist between the plated metal and the sidewall of the opening as the bottom-up plating progresses without a seed layer on the opening sidewall.

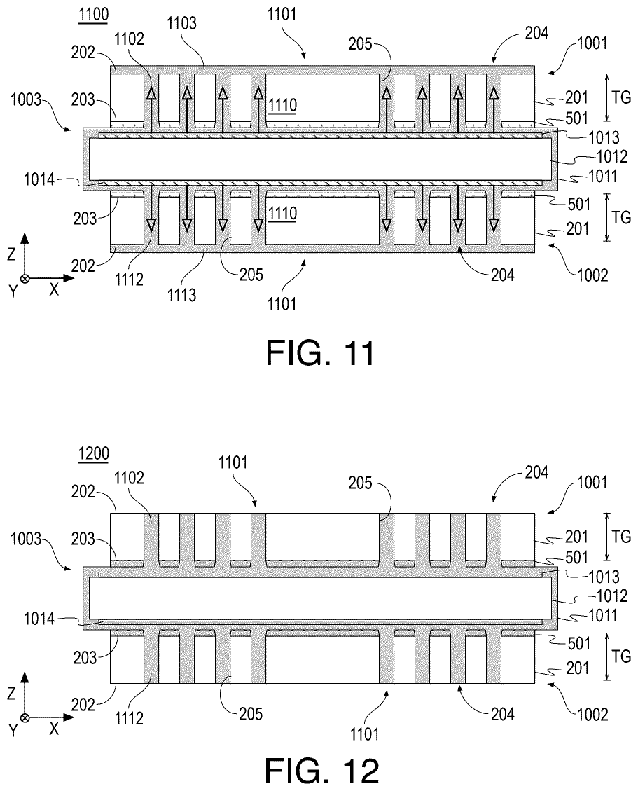

FIG. 11 is an illustration of a cross-sectional side view of a glass substrate structure 1100 similar to glass substrate structure 10000 during and after bottom-up plating 1110 of metal 1101 to form via metallizations 1102 within openings 204 of glass substrate structure 1001 and via metallizations 1112 within openings 204 of glass substrate structure 1002. Such metal plating may also form overburdens 1103, 1113 of metal 1101. As discussed, simultaneous bottom-up plating 1110 progresses up or away from metal seed layer 1011 to fill openings 204 of glass substrate structure 1002 until overburdens 1103, 1113 metal 1101 is evident. Via metallizations 1102, 1112 may be any suitable material such as substantially pure or pure copper. Resultant via metallizations 1102, 1112 or metallization structures may be characterized as through substrate vias (TSVs) or through glass vias (TGVs). Bottom-up plating 1110 may be performed using any suitable technique or techniques such as electrolytic plating techniques using metal seed layer 1011 as a seed and electrode attachment material. Notably, by bottom-up plating 1110 two glass substrate structures 1001, 1002 simultaneously, increased throughput is realized.

Returning to FIG. 1, methods 100 continue at operation 107, where the overburdens due to bottom-up plating may be removed as needed. For example, the plated via metallization may be planarized or polished to remove overburden associated with the plating process and/or to provide a planar surface for continues processing. In some embodiments, the overburdens are removed while the glass substrates are mounted to the peelable plating core. However, the overburdens may be removed after removal from the peelable plating core.

FIG. 12 is an illustration of a cross-sectional side view of a glass substrate structure 1200 similar to glass substrate structure 1100 after overburden removal processing, such as planarization processing, to remove overburdens 1103, 1113 and to form via metallizations 1102, 1112 that have surfaces adjacent second surfaces 203 that are substantially planar with second surfaces 203. As shown, following planarization, via metallizations 1102, 1112 remain only adjacent to sidewalls 205 of openings 204 at second surfaces 203.

Returning to FIG. 1, methods 100 include an optional processing path 114, where preparation for packaging, including formation of an electrical routing structure, are illustrated and discussed after removal of the glass substrates from the peelable plating core. Alternatively, such processing may be performed while the glass substrates are attached to peelable plating core, prior to the peeling process discussed with respect to operation 108. Notably, such one-sided processing of each glass substrate may be conducted while still bonded to the peelable core plating core to result in two one-sided architectures (i.e., an interposer type architecture). In such contexts operations 108-110 may be performed after formation of the electrical routing structure while attached to the peelable plating core. Alternatively, the glass substrates may be removed prior to electrical routing structure fabrication.

Returning to FIG. 1, methods 100 continue at operation 108, where the peelable layer of the peelable plating core is exposed using any suitable technique or techniques. In some embodiments, the peelable layer of the peelable plating core is exposed my trimming or cutting through the outer perimeter of the peelable plating core to expose the peelable layer. In some embodiments, at least the metal seed layer or metal cladding is cut or removed to expose the peelable layer. In some embodiments, the metal seed layer or metal cladding surrounds the core, and the peelable layer is exposed or revealed by cutting through the metal cladding and the core to reveal the peelable layer between the core and the metal cladding.

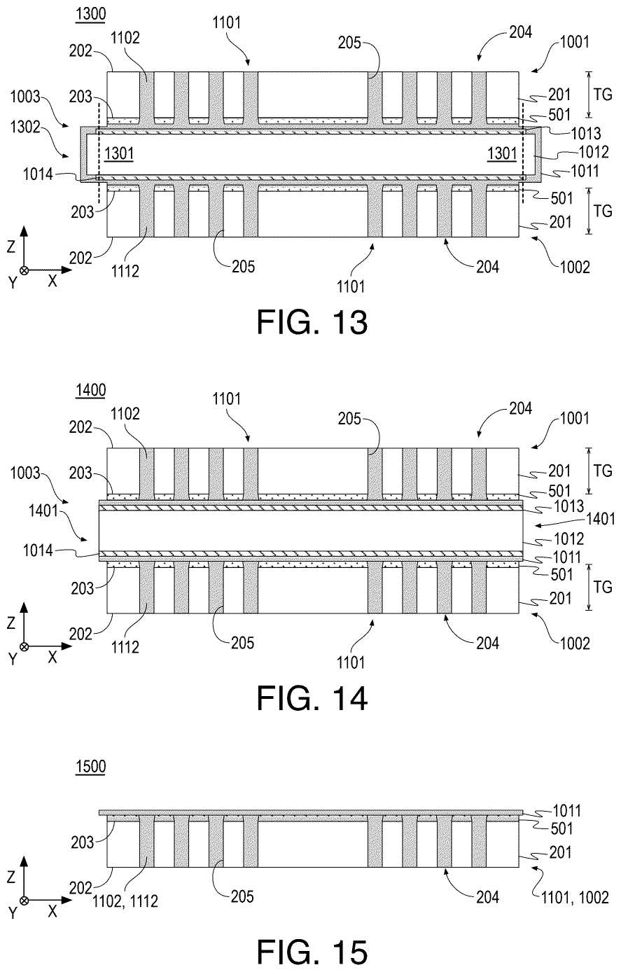

FIG. 13 is an illustration of a cross-sectional side view of a glass substrate structure 1300 similar to glass substrate structure 1200 during the cutting 1301 of at least a portion of an outer perimeter 1302 of peelable plating core 1003. Peelable plating core 1003 may be cut using any suitable technique or techniques such as scoring and blade cutting techniques, laser cutting, or the like. In some embodiments, portions of metal seed layer 1011, peelable layers 1013, 1014, and substrate 1012 are cut to remove portion of outer perimeter 1302. In some embodiments, only a portion of metal seed layer 1011 or portions of metal seed layer 1011 and peelable layers 1013, 1014 are cut to expose peelable layers 1013, 1014.

FIG. 14 is an illustration of a cross-sectional side view of a glass substrate structure 1400 similar to glass substrate structure 1300 after removal of portion of outer perimeter 1302 to provide an exposed edge 1401 of peelable plating core 1003. Exposed edge 1401 of peelable plating core 1003 may be used to peel glass substrate structures 1001, 1002 from peelable plating core 1003. Furthermore, as shown in FIG. 14, only the bond at peelable layers 1013, 1014 remains between glass substrate structures 1001, 1002 and peelable plating core 1003 to provide for relatively easy release of glass substrate structures 1001, 1002 from peelable plating core 1003.

Returning to FIG. 1, methods 100 continue at operation 109, where the peelable layer of the peelable plating core is used to peel or remove the glass substrates from the peelable plating core. The removal of the glass substrates may be performed using any suitable technique or techniques such as mechanical peeling optionally aided by heat treatment or UV release, if applicable.

Methods 100 continue at operation 110, where any necessary cleaning of the peelable layer is performed and the workpiece is further prepared for further processing including assembly into a package as discussed herein below. Any residual of the peelable layer may be removed or cleaned using any suitable technique or techniques such as wet etch or wet clean processing. The workpiece may be further processed by removal of any portion of the metal seed layer, if needed, using planarization techniques for example. In addition or in the alternative the surface of the metal seed layer may be cleaned in preparation for incorporation into a package.

FIG. 15 is an illustration of a cross-sectional side view of a glass substrate structure 1500 similar to glass substrate structure 1400 after removal of glass substrate structures 1001, 1002 from peelable plating core 1003 (which may be discarded or reused), and after removal of any residual of peelable layers 1013, 1014. As discussed, glass substrate structures 1001, 1002 may be removed from peelable plating core 1003 using any suitable technique or techniques such as mechanical peeling. Furthermore, any residuals of peelable layers 1013, 1014 may be removed using a clean processing such as etch, planarization, or the like. As shown, in some embodiments at least a portion of metal seed layer 1011 may remain on glass substrate structures 1001, 1002.

FIG. 16 is an illustration of a cross-sectional side view of a glass substrate structure 1600 similar to glass substrate structure 1500 after removal of metal seed layer 1011. Metal seed layer 1011 may be removed, if needed, using any suitable technique or techniques such as etch and planarization techniques. As shown with respect to enlarged views 911, 511, glass substrate structures 1001, 1002 may have any characteristics discussed herein inclusive of extension 505, top surface portion 506, and so on. Furthermore, via metallizations 1102, 1112 substantially conform to and fill around the discussed glass substrate 201 and polymeric coating structure 501 components discussed herein. Such features and characteristics are not repeated for the sake of brevity.

As discussed, due to the bottom-up fabrication of via metallizations 1102, 1112, via metallizations 1102, 1112 are not rigidly attached to sidewall 205 of glass substrate 201 and, in subsequent thermal processing, the CTE mismatch therebetween does not cause cracking and other failures due to the mechanical decoupling. As shown in enlarged view 1612, in some embodiments, glass substrate structure 1600 includes one or more air gaps 1604 between a portion 1603 of via metallizations 1102, 1112 and a portion 1605 of sidewall 205 of glass substrate 201. Air gap 1604 may be filled with any pertinent ambient gas, in accordance with its use in the art, and air gap 1604 may be characterized as a gap, void, span, or the like. Air gap 1604 may have any suitable distance DAG (distance air gap) between portion 1603 of via metallizations 1102, 1112 and portion 1605 of sidewall 205. In some embodiments, the distance DAG is not less than 10 nm and not more than 100 nm. In some embodiments, the distance DAG is not less than 20 nm and not more than 75 nm. In some embodiments, the distance DAG is not less than 25 nm and not more than 50 nm. In some embodiments, the distance DAG is not less than 30 nm. Other distances may be used. Furthermore, air gaps 1604 may be distributed in any manner through via metallizations 1102, 1112. In some embodiments, portions of via metallizations 1102, 1112 are directly on (i.e., in physical contact with) sidewalls 205 at some positions whereas air gaps 1604 are at other positions. In some embodiments, the percentage of air gap 1604 area to total area within openings 204 is not less than 50%. In some embodiments, the percentage of air gap 1604 area to total area within openings 204 is not less than 75%. Other air gap fractions may be used.

Furthermore, due to the bottom-up plating of via metallizations 1102, 1112, an entirety of each of via metallizations 1102, 1112 are the same material and have the same characteristics. The same material and characteristics include material composition, microstructure, and morphology and extend throughout openings 204. In some embodiments, via metallizations 1102, 1112 are each substantially pure copper. In some embodiments, via metallizations 1102, 1112 are each pure copper. In some embodiments, the entirety of via metallizations 1102, 1112 are substantially pure copper having a shared or constant microstructure as discussed above.

As shown in enlarged view 1613, the polymeric material of polymeric coating structure 501 may extends fully around an inner cross-sectional shape 1606 of openings 204 at second surface 203, and across second surface 203 to other ones of openings 204. For example, extension 505 (see enlarged view 511) may be adjacent to a rim of glass substrate 201 defining inner cross-sectional shape 1606 and top surface portion 506 may extend across second surface 203. Inner cross-sectional shape 1606 may be any suitable shape such as circular (as shown), oval, or the like.

Returning to FIG. 1, methods 100 continue at operation 111, where an electrical routing structure may be built up over at least one side of the glass substrate prior to assembly with an integrated die. The electrical routing structure may be electrically coupled to the through glass vias and may, for example, include one or more levels of metallization features embedded within any suitable dielectric material. The electrical routing structure formed at operation 110 may interconnect one or more IC die to each other and/or couple one or more of IC die to the conductive through vias. Accordingly, the metallization feature pitch of the routing structure is advantageously minimized for highest interconnect density.

FIG. 17 is an illustration of a cross-sectional side view of a package structure 1700 similar to glass substrate structure 1600 after attachment of glass substrate structure 1600 to a handle or carrier 1701 and fabrication or attachment of routing structure 1702. Although illustrated with respect to incorporation of glass substrate structure 1600 into package structures 1700, 1800, 1900, any glass substrate structure discussed herein having any of the discussed characteristics may be deployed in package structures 1700, 1800, 1900. Carrier 1701 may have any suitable composition and may be of any suitable thickness. Furthermore, glass substrate structure 1600 may be attached to carrier 1701 using any suitable technique or techniques such as a removable adhesive, a releasable tape, or the like.

Although illustrated with respect to routing structure (or redistribution layer) formed over second surface 203, in some embodiments two-sided architectures include a redistribution layer over both first surface 202 and second surface 203. In some embodiments, routing structure 1702 is built-up over second surface 203. In other embodiments a routing structure is built-up over first surface 202 or a routing structure is built up over both first surface 202 and second surface 203. As shown, routing structure 1702 includes one or more levels of redistribution layer (RDL) metallization features 1703 embedded within one or more layers of dielectric material 1704. RDL metallization features 1703 may include any suitable metal such as copper. In some embodiments, a portion of RDL metallization features 1703 are to electrically bridge together two or more IC dies, preferably with a fine metallization feature pitch as enabled by the improved flatness profile of glass substrate 201 as compared to traditional organic preform cores. Furthermore, a portion of routing structure 1702 further includes metallization features 1703 that are to interconnect IC dies to via metallizations 1112.

Dielectric material 1704 may be any suitable material or materials such as a molding compound, a spin-on material, or a dry film laminate material. In some embodiments, dielectric material 1704 is applied in a wet or uncured state into a cast and is then dried or cured. Alternatively, dielectric material 1704 may be applied as a semi-cured dry film that is fully cured following its application to glass substrate 201. The composition of dielectric material 1704 may include one or more of an organic dielectric material, such as, an epoxy resin, phenolic-glass, or a resinous film such as the GX-series films commercially available from Ajinomoto Fine-Techno Co., Inc. (ABF). Exemplary epoxy resins for deployment in dielectric material 1704 include an acrylate of novolac such as epoxy phenol novolacs (EPN) or epoxy cresol novolacs (ECN). In some embodiments, dielectric material 1704 is a bisphenol-A epoxy resin including epichlorohydrin, for example. In some embodiments, dielectric material 1704 includes an aliphatic epoxy resin.

Returning to FIG. 1, methods 100 continue at operation 112, where at least one IC die is assembled to the workpiece. In some embodiments, the one or more IC dies are attached to the electrical routing structure formed at operation 110. The one or more IC dies assembled at operation 111 may each include any electrical circuitry. In some embodiments, one or more of the IC dies include logic circuitry including logic gates. The one or more IC dies assembled at operation 111 may also include any photonic circuitry suitable for the detection, emission or processing (e.g., filtering, multiplexing and demultiplexing) of optical signals.

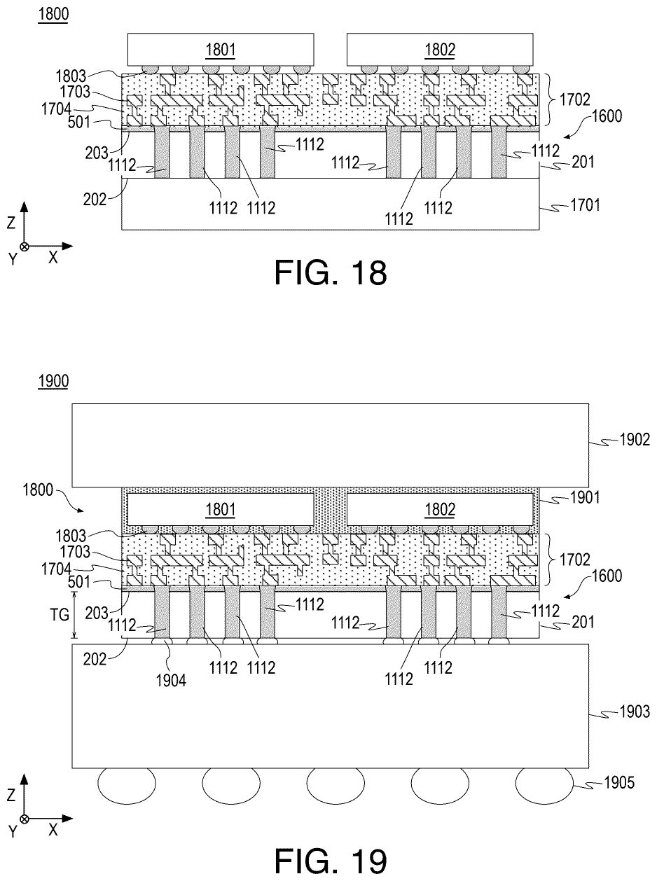

FIG. 18 is an illustration of a cross-sectional side view of a package structure 1800 similar to package structure 1700 after attachment of any number of IC dies such as IC dies 1801, 1802 to routing structure 1702 using intervening electrical interconnects 1803. As shown, IC dies 1801, 1802 are assembled to interconnect interfaces within a top metallization level of routing structure 1702 of an assembled package structure 1800. Although illustrated with two IC dies 1801, 1802, package structure 1800 may include any number of IC dies. In some embodiments, IC dies 1801, 1802 are the first level of dies of a packaged multi-die IC device package structure. IC dies 1801, 1802 may be directly bonded to routing structure 1702, or, electrically coupled through intervening electrical interconnects 1803, which may include solder of any suitable composition. In the example illustrated, IC dies 1801, 1802 are each flip-chip attached with integrated circuitry within each die being proximal to a top surface of routing structure 1702. In alternative embodiments, IC dies 1801, 1802 include through die vias (not shown) with integrated circuity being distal from the top surface of routing structure 1702.

IC dies 1801, 1802 may include any suitable circuitry. In some embodiments, at least one of IC dies 1801, 1802 is a fully functional ASIC. In some embodiments, IC dies 1801, 1802 include a chiplet or tile that has more limited functionality supplementing the function of one or more others of IC dies 1801, 1802 that are to be part of the same multi-die device. A chiplet or tile may, for example, be any of a wireless radio circuit, microprocessor core, electronic memory circuit, floating point gate array (FPGA), power management and/or power supply circuit, or a MEMS device. In some examples, one or more of IC dies 1801, 1802 includes one or more banks of active repeater circuitry to improve multi-die interconnects (e.g., network-on-chip architectures). In other examples, one or more of IC dies 1801, 1802 includes clock generator circuitry or temperature sensing circuitry. In other examples, one or more of IC dies 1801, 1802 includes logic circuitry that, along with other IC dies 1801, 1802 implement multi-chiplet aggregated logic circuitry (e.g., mesh network-on-chip architectures). In some specific examples, at least one of IC dies 1801, 1802 includes microprocessor core circuitry, for example including one or more shift registers. IC dies 1801, 1802 may include field effect transistors (FETs) with a device pitch of 80 nm, or less. The FETs may be of any architecture (e.g., planar, non-planar, single-gate, multi-gate, stacked nanosheet, etc.). Additionally or in the alternative, IC dies 1801, 1802 may include active devices other than FETs such as magnetic tunnel junctions (MTJs), capacitors, or the like. In some embodiments, IC dies 1801, 1802 include one or more IC die metallization levels embedded within an insulator.

Returning to FIG. 1, methods 100 continue at operation 113, where the final device is packaged, assembled, and output, for example, by attachment of a package to a host component. The assembly or package may be installed in any suitable electronic device such as a laptop, a netbook, a notebook, an ultrabook, a smartphone, a tablet, a personal digital assistant PDA, an ultra-mobile PC, a mobile phone, a desktop computer, a server, a printer, a scanner, a monitor, a set-top box, an entertainment control unit, a digital camera, a portable music player, a digital video recorder, or the like.

FIG. 19 is an illustration of a cross-sectional side view of a package structure 1900 similar to package structure 1800 after attachment to a host component 1903 and deployment of one or more heat spreaders and/or heat sinks 1902. As shown, package structure 1900, which may be characterized as a system, includes package structure 1800 attached to host component 1903 with interconnects 1904. In some embodiments, interconnects 1904 are solder (e.g., SAC) microbumps although other interconnect features may be used. In some embodiments, host component 1903 is predominantly silicon. Host component 1903 may also include one or more alternative materials known to be suitable as interposers or package substrates (e.g., an epoxy preform, cored or coreless laminate board, etc.). In some embodiments, host component 1903 is a printed circuit board (PCB). In some embodiments, host component 1903 includes one or more metallized redistribution levels (not depicted) embedded within a dielectric material. Host component 1903 may also include one or more IC dies, one or more passive or active components, or the like embedded therein.

Host component 1903 may include interconnects 1905 which may include solder (e.g., ball, bump, etc.) suitable for a given host board architecture (e.g., surface mount FR4, etc.). Also as shown, one or more heat spreaders and/or heat sinks 1902 may be coupled to package structure 1800, which may be advantageous, for example, where IC dies 1801, 1802 include one or more CPU cores or other circuitry of similar power density. Any package dielectric 1901, such as a mold material, may surround sidewalls of IC dies 1801, 1802. Although not illustrated, package dielectric 1901 may be ground down to a top surface of IC dies 1801, 1802 such that heat spreader/sink 1902 may be in closer contact with IC dies 1801, 1802.

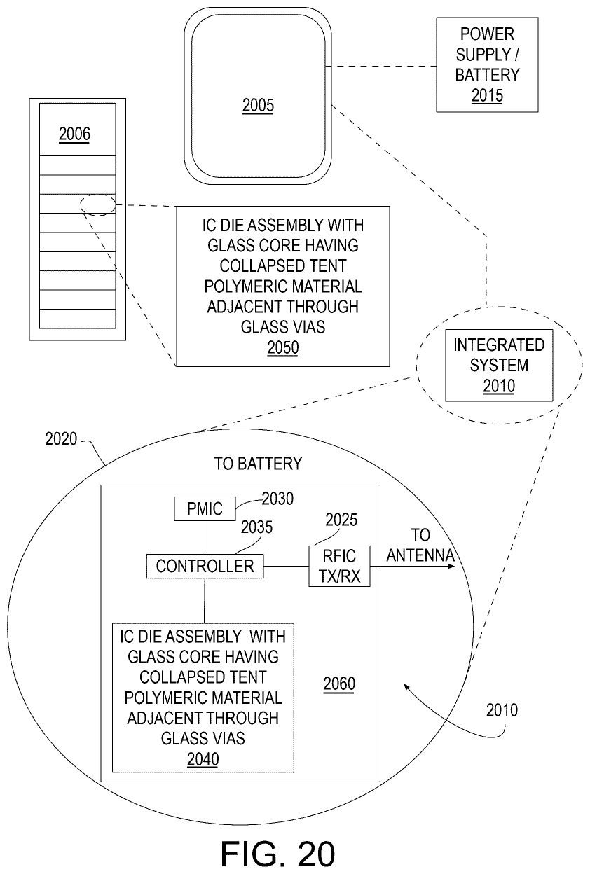

FIG. 20 illustrates exemplary systems employing an IC assembly including a glass core substrate with bottom-up plated through glass vias, arranged in accordance with at least some implementations of the present disclosure. The system may be a mobile computing platform 2005 and/or a data server machine 2006, for example. Either may employ a component assembly including an IC assembly including a glass core substrate with bottom-up plated through glass vias as described elsewhere herein. Server machine 2006 may be any commercial server, for example including any number of high-performance computing platforms disposed within a rack and networked together for electronic data processing, which in the exemplary embodiment includes an IC die assembly 2050 with a glass core substrate with bottom-up plated through glass vias as described elsewhere herein. Mobile computing platform 2005 may be any portable device configured for each of electronic data display, electronic data processing, wireless electronic data transmission, or the like. For example, mobile computing platform 2005 may be any of a tablet, a smart phone, a laptop computer, etc., and may include a display screen (e.g., a capacitive, inductive, resistive, or optical touchscreen), a chip-level or package-level integrated system 2010, and a battery 2015 and/or power supply circuitry. Although illustrated with respect to mobile computing platform 2005, in other examples, chip-level or package-level integrated system 2010 and battery 2015 may be implemented in a desktop computing platform, an automotive computing platform, an internet of things platform, or the like. As discussed below, in some examples, the disclosed systems may include a sub-system 2060 such as a system on a chip (SOC) or an integrated system of multiple ICs, which is illustrated with respect to mobile computing platform 2005.

Whether disposed within integrated system 2010 illustrated in expanded view 2020 or as a stand-alone packaged device within data server machine 2006, sub-system 2060 may include memory circuitry and/or processor circuitry 2040 (e.g., RAM, a microprocessor, a multi-core microprocessor, graphics processor, etc.), a power management integrated circuit (PMIC) 2030, a controller 2035, and a radio frequency integrated circuit (RFIC) 2025 (e.g., including a wideband RF transmitter and/or receiver (TX/RX)). As shown, one or more IC dies, such as memory circuitry and/or processor circuitry 2040 may be assembled and implemented such that one or more have an IC assembly including a glass core substrate with bottom-up plated through glass vias as described herein. In some embodiments, RFIC 2025 includes a digital baseband and an analog front-end module further including a power amplifier on a transmit path and a low noise amplifier on a receive path. Functionally, PMIC 2030 may perform battery power regulation, DC-to-DC conversion, etc., and so has an input coupled to battery 2015, and an output providing a current supply to other functional modules. As further illustrated in FIG. 20, in the exemplary embodiment, RFIC 2025 has an output coupled to an antenna (not shown) to implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. Memory circuitry and/or processor circuitry 2040 may provide memory functionality for sub-system 2060, high level control, data processing and the like for sub-system 2060. In alternative implementations, each of the SOC modules may be integrated onto separate ICs coupled to a package substrate, interposer, or board.

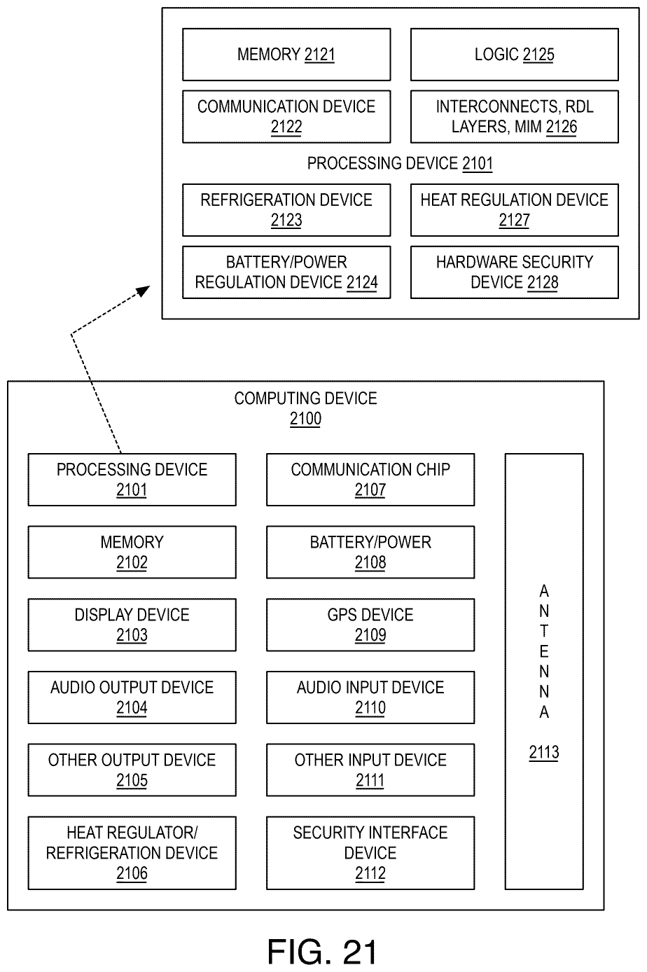

FIG. 21 is a block diagram of a computing device 2100, in accordance with some embodiments. For example, one or more components of computing device 2100 may include any of the package structures or assemblies having a glass core substrate with bottom-up plated through glass vias as discussed elsewhere herein. A number of components are illustrated in FIG. 21, but any one or more of these components may be omitted or duplicated, as suitable for the application. In some embodiments, some of the components included in computing device 2100 may be attached to one or more printed circuit boards (e.g., a motherboard). In some embodiments, various ones of these components may be fabricated onto a single system-on-a-chip (SoC) die or implemented with a disintegrated plurality of chiplets or tiles packaged together. Any of such packaged components may include a glass core substrate with bottom-up plated through glass vias, for example, as discussed herein. Additionally, in various embodiments, computing device 2100 may not include one or more of the components illustrated in FIG. 21, but computing device 2100 may include interface circuitry for coupling to the one or more components. For example, computing device 2100 may not include a display device 2103, but may include display device interface circuitry (e.g., a connector and driver circuitry) to which display device 2103 may be coupled.

Computing device 2100 may include a processing device 2101 (e.g., one or more processing devices). As used herein, the term processing device or processor indicates a device that processes electronic data from registers and/or memory to transform that electronic data into other electronic data that may be stored in registers and/or memory. Processing device 2101 may include a memory 2121, a communication device 2122, a refrigeration/active cooling device 2123, a battery/power regulation device 2124, logic 2125, interconnects 2126, a heat regulation device 2127, and a hardware security device 2128.

Processing device 2101 may include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable compute units.

Processing device 2101 may include a memory 2102, which may itself include one or more memory devices such as volatile memory (e.g., dynamic random-access memory (DRAM)), nonvolatile memory (e.g., read-only memory (ROM)), flash memory, solid state memory, and/or a hard drive. In some embodiments, processing device 2101 shares a package with memory 2102. This memory may be used as cache memory and may include embedded dynamic random-access memory (eDRAM) or spin transfer torque magnetic random-access memory (STT-M RAM).

Computing device 2100 may include a heat regulation/refrigeration device 2106. Heat regulation/refrigeration device 2106 may maintain processing device 2101 (and/or other components of computing device 2100) at a predetermined low temperature during operation. This predetermined low temperature may be any temperature discussed elsewhere herein.

In some embodiments, computing device 2100 may include a communication chip 2107 (e.g., one or more communication chips). For example, the communication chip 2107 may be configured for managing wireless communications for the transfer of data to and from computing device 2100. The term “wireless” and its derivatives may be used to describe circuits, devices, systems, methods, techniques, communications channels, etc., that may communicate data through the use of modulated electromagnetic radiation through a nonsolid medium.

Computing device 2100 may include any photonics structure discussed herein that may facilitate communication between one or more instances of processing device 2101 and/or one or more instances of memory 2102, for example.

Computing device 2100 may include battery/power circuitry 2108. Battery/power circuitry 2108 may include one or more energy storage devices (e.g., batteries or capacitors) and/or circuitry for coupling components of computing device 2100 to an energy source separate from computing device 2100 (e.g., AC line power).

Computing device 2100 may include a display device 2103 (or corresponding interface circuitry, as discussed above). Display device 2103 may include any visual indicators, such as a heads-up display, a computer monitor, a projector, a touchscreen display, a liquid crystal display (LCD), a light-emitting diode display, or a flat panel display, for example.

Computing device 2100 may include an audio output device 2104 (or corresponding interface circuitry, as discussed above). Audio output device 2104 may include any device that generates an audible indicator, such as speakers, headsets, or earbuds, for example.

Computing device 2100 may include an audio input device 2110 (or corresponding interface circuitry, as discussed above). Audio input device 2110 may include any device that generates a signal representative of a sound, such as microphones, microphone arrays, or digital instruments (e.g., instruments having a musical instrument digital interface (MIDI) output).

Computing device 2100 may include a global positioning system (GPS) device 2109 (or corresponding interface circuitry, as discussed above). GPS device 2109 may be in communication with a satellite-based system and may receive a location of computing device 2100, as known in the art.

Computing device 2100 may include another output device 2105 (or corresponding interface circuitry, as discussed above). Examples include an audio codec, a video codec, a printer, a wired or wireless transmitter for providing information to other devices, or an additional storage device.

Computing device 2100 may include another input device 2111 (or corresponding interface circuitry, as discussed above). Examples may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

Computing device 2100 may include a security interface device 2112. Security interface device 2112 may include any device that provides security measures for computing device 2100 such as intrusion detection, biometric validation, security encode or decode, managing access lists, malware detection, or spyware detection.

Computing device 2100 may include an antenna 2113. Antenna 2113 may include any device that translates electrical current to radio waves and/or translates radio waves to electrical current.

Computing device 2100, or a subset of its components, may have any appropriate form factor, such as a server or other networked computing component, a mobile device, a printer, a scanner, a monitor, a set-top box, an entertainment control unit, a vehicle control unit, a digital camera, a digital video recorder, or a wearable computing device.

While certain features set forth herein have been described with reference to various implementations, this description is not intended to be construed in a limiting sense. Hence, various modifications of the implementations described herein, as well as other implementations, which are apparent to persons skilled in the art to which the present disclosure pertains are deemed to lie within the spirit and scope of the present disclosure.

It will be recognized that the invention is not limited to the embodiments so described, but can be practiced with modification and alteration without departing from the scope of the appended claims. For example, the above embodiments may include specific combinations of features as further provided below.

The following pertain to exemplary embodiments.

In one or more first embodiments, an apparatus comprises a glass substrate having a thickness extending between a first surface and an opposing second surface thereof, an opening extending from the first surface through the thickness of the glass substrate to the second surface, the opening defining a sidewall of the glass substrate within the opening, a polymeric material structure on a portion of the sidewall within the opening immediately adjacent the first surface, such that the polymeric material structure comprises a convex surface opposite the portion of the sidewall, and a via metallization within the opening and extending from the first surface through the thickness of the glass substrate to the second surface, the via metallization having a first portion directly on the polymeric material structure within the opening.

In one or more second embodiments, further to the first embodiments, the apparatus further comprises second polymeric material structure having a same composition as the polymeric material structure on a portion of the first surface adjacent the sidewall.

In one or more third embodiments, further to the first or second embodiments, the second polymeric material structure comprises a second convex surface opposite the portion of the first surface.

In one or more fourth embodiments, further to the first through third embodiments, an edge of the opening defined by the portion of the first surface and the portion of the sidewall is absent the polymeric material structure and the second polymeric material structure.

In one or more fifth embodiments, further to the first through fourth embodiments, the apparatus further comprises an air gap between a second portion of the via metallization and a second portion of the sidewall of the glass substrate within the opening.

In one or more sixth embodiments, further to the first through fifth embodiments, the polymeric material structure comprises one of an epoxy material, a polyimide material, a benzocyclobutene based material, a polyethylene terephthalate based material, or a polyethylene based material, and such that an entirety of the via metallization is substantially pure copper.

In one or more seventh embodiments, further to the first through sixth embodiments, the polymeric material structure comprises a first polymeric material directly on the portion of the sidewall within the opening and a second polymeric material directly on the first polymeric material.

In one or more eighth embodiments, further to the first through seventh embodiments, the apparatus further comprises an integrated circuit (IC) die over the first surface or the second surface of the glass substrate, such that the IC is electrically coupled to the via metallization and the glass substrate is a layer of glass having a thickness of not less than 50 μm, a first length of not less than 10 mm and a second length orthogonal to the first length of not less than 10 mm.

In one or more ninth embodiments, a method comprises depositing a polymeric material over a first surface of a glass substrate comprising openings extending from the first surface to an opposing second surface of the glass substrate, such that the polymeric material seals the openings at the first surface, pulling a vacuum over the first surface of the glass substrate to collapse the polymeric material into the openings to at least partially expose the openings at the first surface, and plating via metallizations within the openings.

In one or more tenth embodiments, further to the ninth embodiments, depositing the polymeric material comprises one of a slit coating process, a spin coating process, or a spray coating process.

In one or more eleventh embodiments, further to the ninth or tenth embodiments, pulling the vacuum forms a portion of the polymeric material on a portion of a sidewall within at least one of the openings, the portion of the polymeric material having a convex surface opposite the portion of the sidewall.

In one or more twelfth embodiments, further to the ninth through eleventh embodiments, pulling the vacuum forms a second portion of the polymeric material on a portion of the first surface adjacent the sidewall, the second portion of the polymeric material having a second convex surface opposite the portion of the first surface.

In one or more thirteenth embodiments, further to the ninth through twelfth embodiments, the polymeric material comprises one of an epoxy material, a polyimide material, a benzocyclobutene based material, a polyethylene terephthalate based material, or a polyethylene based material.

In one or more fourteenth embodiments, further to the ninth through thirteenth embodiments, the method further comprises attaching the polymeric material to a metal cladding on a first surface of a substrate core, and attaching a second polymeric material over a first surface of a second glass substrate to the metal cladding on a second surface of the substrate core opposite the first surface, such that plating the via metallizations within the openings further comprises plating second via metallizations within second openings in the second glass substrate.

In one or more fifteenth embodiments, a method comprises coupling a first polymeric material on a first glass substrate to a metal cladding on a first side of a core and a second polymeric material on a second glass substrate to the metal cladding on a second side of the core, such that the first glass substrate comprises first openings extending through a first thickness of the first glass substrate, and the second glass substrate comprises second openings extending through a second thickness of the second glass substrate, simultaneously plating first via metallizations in the first openings and second via metallizations in the second openings, and removing the first glass substrate and the second glass substrate from the core.

In one or more sixteenth embodiments, further to the fifteenth embodiments, the metal cladding surrounds the core, and removing the first glass substrate and the second glass substrate comprises cutting through the metal cladding and the core to reveal a peelable layer between the core and the metal cladding, and peeling first glass substrate and the second glass substrate from the core using the peelable layer.

In one or more seventeenth embodiments, further to the fifteenth or sixteenth embodiments, the metal cladding, the first via metallizations, and the second via metallizations each comprise copper.

In one or more eighteenth embodiments, further to the fifteenth through seventeenth embodiments, the method further comprises depositing the first polymeric material over a first surface of the first glass substrate, such that the first polymeric material seals the first openings at the first surface of the first glass substrate, and collapsing the first polymeric material to expose the first openings at the first surface of the first glass substrate.

In one or more nineteenth embodiments, further to the fifteenth through eighteenth embodiments, depositing the first polymeric material comprises a slit coating of the first surface of the first glass substrate, and such that collapsing the first polymeric material comprises pulling a vacuum over the first surface of the first glass substrate.

In one or more twentieth embodiments, further to the fifteenth through nineteenth embodiments, the first polymeric material comprises one of an epoxy material, a polyimide material, a benzocyclobutene based material, a polyethylene terephthalate based material, or a polyethylene based material.

It will be recognized that the invention is not limited to the embodiments so described, but can be practiced with modification and alteration without departing from the scope of the appended claims. For example, the above embodiments may include specific combination of features. However, the above embodiments are not limited in this regard and, in various implementations, the above embodiments may include undertaking only a subset of such features, undertaking a different order of such features, undertaking a different combination of such features, and/or undertaking additional features than those features explicitly listed. The scope of the invention should, therefore, be determined with reference to the appended claims, along with the full scope of equivalents to which such claims are entitled.

What is claimed is:

1. An apparatus, comprising:
a glass substrate having a thickness extending between a first surface and an opposing second surface thereof;
an opening extending from the first surface through the thickness of the glass substrate to the second surface, the opening defining a sidewall of the glass substrate within the opening;
a polymeric material structure on a portion of the sidewall within the opening immediately adjacent the first surface, wherein the polymeric material structure comprises a convex surface opposite the portion of the sidewall; and
a via metallization within the opening and extending from the first surface through the thickness of the glass substrate to the second surface, the via metallization having a first portion directly on the polymeric material structure within the opening.

2. The apparatus of claim 1, further comprising:
a second polymeric material structure having a same composition as the polymeric material structure on a portion of the first surface adjacent the sidewall.

3. The apparatus of claim 2, wherein the second polymeric material structure comprises a second convex surface opposite the portion of the first surface.

4. The apparatus of claim 2, wherein an edge of the opening defined by the portion of the first surface and the portion of the sidewall is absent the polymeric material structure and the second polymeric material structure.

5. The apparatus of claim 1, further comprising an air gap between a second portion of the via metallization and a second portion of the sidewall of the glass substrate within the opening.

6. The apparatus of claim 1, wherein the polymeric material structure comprises one of an epoxy material, a polyimide material, a benzocyclobutene based material, a polyethylene terephthalate based material, or a polyethylene based material, and wherein an entirety of the via metallization is substantially pure copper.

7. The apparatus of claim 1, wherein the polymeric material structure comprises a first polymeric material directly on the portion of the sidewall within the opening and a second polymeric material directly on the first polymeric material.

8. The apparatus of claim 1, further comprising:
an integrated circuit (IC) die over the first surface or the second surface of the glass substrate, wherein the IC is electrically coupled to the via metallization and the glass substrate is a layer of glass having a thickness of not less than 50 μm, a first length of not less than 10 mm and a second length orthogonal to the first length of not less than 10 mm.

9. A method, comprising:
depositing a polymeric material over a first surface of a glass substrate comprising openings extending from the first surface to an opposing second surface of the glass substrate, wherein the polymeric material seals the openings at the first surface;
pulling a vacuum over the first surface of the glass substrate to collapse the polymeric material into the openings to at least partially expose the openings at the first surface; and
plating via metallizations within the openings.

10. The method of claim 9, wherein depositing the polymeric material comprises one of a slit coating process, a spin coating process, or a spray coating process.

11. The method of claim 9, wherein pulling the vacuum forms a portion of the polymeric material on a portion of a sidewall within at least one of the openings, the portion of the polymeric material having a convex surface opposite the portion of the sidewall.

12. The method of claim 11, wherein pulling the vacuum forms a second portion of the polymeric material on a portion of the first surface adjacent the sidewall, the second portion of the polymeric material having a second convex surface opposite the portion of the first surface.

13. The method of claim 9, wherein the polymeric material comprises one of an epoxy material, a polyimide material, a benzocyclobutene based material, a polyethylene terephthalate based material, or a polyethylene based material.

14. The method of claim 9, further comprising:
attaching the polymeric material to a metal cladding on a first surface of a substrate core; and
attaching a second polymeric material over a first surface of a second glass substrate to the metal cladding on a second surface of the substrate core opposite the first surface, wherein plating the via metallizations within the openings further comprises plating second via metallizations within second openings in the second glass substrate.

15. A method, comprising:
coupling a first polymeric material on a first glass substrate to a metal cladding on a first side of a core and a second polymeric material on a second glass substrate to the metal cladding on a second side of the core, wherein the first glass substrate comprises first openings extending through a first thickness of the first glass substrate, and the second glass substrate comprises second openings extending through a second thickness of the second glass substrate;
simultaneously plating first via metallizations in the first openings and second via metallizations in the second openings; and
removing the first glass substrate and the second glass substrate from the core.

16. The method of claim 15, wherein the metal cladding surrounds the core, and removing the first glass substrate and the second glass substrate comprises cutting through the metal cladding and the core to reveal a peelable layer between the core and the metal cladding, and peeling first glass substrate and the second glass substrate from the core using the peelable layer.

17. The method of claim 16, wherein the metal cladding, the first via metallizations, and the second via metallizations each comprise copper.

18. The method of claim 15, further comprising:
depositing the first polymeric material over a first surface of the first glass substrate, wherein the first polymeric material seals the first openings at the first surface of the first glass substrate; and
collapsing the first polymeric material to expose the first openings at the first surface of the first glass substrate.

19. The method of claim 18, wherein depositing the first polymeric material comprises a slit coating of the first surface of the first glass substrate, and wherein collapsing the first polymeric material comprises pulling a vacuum over the first surface of the first glass substrate.

20. The method of claim 15, wherein the first polymeric material comprises one of an epoxy material, a polyimide material, a benzocyclobutene based material, a polyethylene terephthalate based material, or a polyethylene based material.
